(19) United States
(12) Patent Application Publication
(10) Pub. No.: US 2024/0155769 A1
(43) Pub. Date: May 9, 2024

(54) METHOD FOR FORMING FUNCTIONAL LAYER, METHOD FOR MANUFACTURING ELECTRONIC COMPONENT, AND ELECTRONIC COMPONENT INCLUDING FUNCTIONAL LAYER

(71) Applicants: Yukihiro WAKABAYASHI, Kanagawa (JP); Takashi FUJITA, Kanagawa (JP); Hiroyuki HIRATSUKA, Kanagawa (JP); Kohji TAKEUCHI, Kanagawa (JP); Tohru HASEGAWA, Kanagawa (JP); Hirotaka UNNO, Kanagawa (JP)

(72) Inventors: Yukihiro WAKABAYASHI, Kanagawa (JP); Takashi FUJITA, Kanagawa (JP); Hiroyuki HIRATSUKA, Kanagawa (JP); Kohji TAKEUCHI, Kanagawa (JP); Tohru HASEGAWA, Kanagawa (JP); Hirotaka UNNO, Kanagawa (JP)

(73) Assignee: Ricoh Company, Ltd., Tokyo (JP)

(21) Appl. No.: 18/497,373

(22) Filed: Oct. 30, 2023

(30) Foreign Application Priority Data
Nov. 8, 2022 (JP) 2022-179118
May 9, 2023 (JP) 2023-077506

(51) Int. Cl. H05K 1/18; H05K 1/02

(52) U.S. Cl. CPC H05K 1/181; H05K 1/0287; H05K 2201/09972

(57) ABSTRACT

A method for forming a functional layer includes giving information to the functional layer while forming the functional layer on a surface of an object. The functional layer includes an information area having the information and a non-information area other than the information area. The information area is different in color from the non-information area.

### CROSS-REFERENCE TO RELATED APPLICATIONS

This patent application is based on and claims priority pursuant to 35 U.S.C. § 119(a) to Japanese Patent Application Nos. 2022-179118, filed on Nov. 8, 2022, and 2023-077506, filed on May 9, 2023, in the Japan Patent Office, the entire disclosure of which is hereby incorporated by reference herein.

### BACKGROUND

### Technical Field

Embodiments of the present disclosure relate to a method for forming a functional layer, a method for manufacturing an electronic component, and an electronic component including the functional layer.

### Related Art

A functional-layer-provided electronic component, which is an electronic component on which a functional layer is formed, is known in the art. The functional-layer-provided electronic component includes, for example, a semiconductor component and a semiconductor package component which is a semiconductor component covered with a package. Such a functional-layer-provided electronic component is mounted on, for example, a printed circuit board (PCB) substrate or a printed wiring board (PWB) substrate, and is used in applications such as high-speed communication, 5G, and automatic driving.

Further, as a method for manufacturing an electronic component having a functional layer with information, which is a functional layer to which information is given, a method for manufacturing an electronic circuit module is known that includes a burying layer provided on a first principal surface of a circuit board with the electronic component buried therein. The outer surface of the burying layer includes a marking having a protruding shape that protrudes with respect to the outer surface of the burying layer.

### SUMMARY

An embodiment of the present disclosure includes a method for forming a functional layer. The method includes giving information to the functional layer while forming the functional layer on a surface of an object. The functional layer includes an information area having the information and a non-information area other than the information area. The information area is different in color from the non-information area.

An embodiment of the present disclosure includes a method for manufacturing an electronic component. The method includes forming a functional layer to which information is provided according to the method of claim 1. The object is the electronic component.

An embodiment of the present disclosure includes an electronic component including a functional layer as a surface layer. The functional layer includes an information area and a non-information area, and having a uniform thickness. Information is given to the information area by a pattern shape having a color difference different from the non-information area.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a diagram illustrating an overall configuration of a manufacturing apparatus for manufacturing a functional-layer-provided electronic component, according to Embodiment of the present disclosure;

FIG. 2 is a diagram illustrating a hardware configuration of a controller of the manufacturing apparatus of FIG. 1;

FIG. 3 is a diagram illustrating a functional configuration of the controller of the manufacturing apparatus of FIG. 1;

FIG. 4 is a flowchart of forming a functional layer with information, according to Embodiment 1 of the present disclosure;

FIG. 5 is a schematic top view of the functional-layer-provided electronic component manufactured by a manufacturing method, according to an embodiment of the present disclosure;

FIG. 6 is an enlarged top view of a first example of an area VI in FIG. 5;

FIG. 7 is an enlarged top view of a second example of the area VI in FIG. 5;

FIG. 8 is an enlarged top view of a third example of the area VI in FIG. 5;

FIG. 9 is a cross-sectional view of a first example of the functional-layer-provided electronic component taken through a line IX-IX of FIG. 5;

FIG. 10 is a cross-sectional view of a second example of the functional-layer-provided electronic component taken through the line IX-IX of FIG. 5;

FIG. 11 is a cross-sectional view of a third example of the functional-layer-provided electronic component taken through the line IX-IX of FIG. 5;

FIG. 12 is a top view of a first example of a dot indicating information given to a functional layer, according to an embodiment of the present disclosure;

FIG. 13 is a top view of a second example of a dot indicating information given to a functional layer, according to an embodiment of the present disclosure;

FIG. 14 is a top view of a first example of a two-dimensional code given to a functional layer, according to an embodiment of the present disclosure;

FIG. 15 is an enlarged top view of an area XV in FIG. 14;

FIG. 16 is a top view of a second example of a two-dimensional code given to a functional layer, according to an embodiment of the present disclosure;

FIG. 17 is an enlarged top view of an area XVII in FIG. 16;

FIG. 18 is a top view of a third example of a two-dimensional code given to a functional layer, according to an embodiment of the present disclosure;

FIG. 19 is an enlarged top view of an area XIX in FIG. 18;

FIG. 20 is a top view of an example of the functional-layer-provided electronic component manufactured by a manufacturing method, according to an embodiment of the present disclosure;

FIG. 21 is a block diagram illustrating an overall configuration of a manufacturing apparatus for manufacturing a functional-layer-provided electronic component, according to Embodiment 2 of the present disclosure;

FIG. 22 is a flowchart of forming a functional layer with information, according to Embodiment 2 of the present disclosure;

FIG. 23 is a top view of a functional-layer-provided electronic component, according to Embodiment 3 of the present disclosure;

FIG. 24 is a cross-sectional view taken through a line XXIV-XXIV of FIG. 23;

FIG. 25 is a view of an example of a process of forming a functional layer on an electronic component, according to Embodiment 3 of the present disclosure; and

FIG. 26 is another view of an example of a process of forming a functional layer on an electronic component, according to Embodiment 3 of the present disclosure.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

Embodiments of the present disclosure are described below in detail with reference to the drawings. In the drawings, like reference signs denote like elements, and overlapping description may be simplified or omitted as appropriate.

In the drawings, the Cartesian coordinate system having an X-axis, a y-axis, and a Z-axis is used to express directions.

The X-axis, the Y-axis, and the Z-axis are substantially orthogonal to each other. A Z direction indicates the thickness direction of a functional layer formed in an electronic component according to embodiments of the present disclosure. A positive Z direction side is referred to as upper, and a negative Z direction side is referred to lower.

However, the above-described direction expressions do not limit the direction of embodiments of the present disclosure.

The functional layer according to embodiments of the present disclosure includes a layer that is formed on a surface of the electronic component and has a function of shielding, i.e., blocking electromagnetic waves for waterproof, moisture-proof, heat dissipation, rust-proof, gas-proof, measures against static electricity, and measures against electromagnetic interference (EMI). Further, a layer having the function of shielding electromagnetic waves includes a layer having a function of shielding at least one of electromagnetic waves generated from an electronic component ore electromagnetic waves incident on the electronic component from the outside. In the following description, the layer having the function of shielding electromagnetic waves may be referred to as an “electromagnetic wave shielding layer.” The functional layer according to embodiments of the present disclosure may have a function other than the above-described functions.

The functional layer according to embodiments of the present disclosure includes an insulating material or a conductive material. A shield layer formed of an insulating material is used for, for example, waterproof, moisture-proof, heat dissipation, rust-proof, gas-proof, and measures against static electricity. The electromagnetic wave shielding layer is formed of, for example, a conductive material. In the case of the electromagnetic wave shielding layer, a protective layer formed of an insulating material may be further formed on the electromagnetic wave shielding layer in order to reduce corrosion, sulfurization, and oxidation of the conductive material. Various resin materials can be used as the insulating material. As the conductive material, for example, nanoparticles made of Au, Ag, Cu, or Ni, or liquid metal material containing complex ink can be used. However, the material forming the functional layer according to embodiments of the present disclosure is not limited to the insulating material or the conductive material, and can be appropriately selected depending on usage.

The electronic component according to embodiments of the present disclosure includes a semiconductor component, a semiconductor package component, which is a semiconductor component covered with a package, and a semiconductor module. As the electronic component in the present disclosure, for example, a semiconductor component or a semiconductor package component manufactured by Ricoh Co., Ltd. can be used. The electronic component is an object according to embodiments of the present disclosure. The term “object” refers to an object for which a functional layer is to be formed.

The functional-layer-provided electronic component according to embodiments of the present disclosure includes a semiconductor component, a semiconductor package component, a semiconductor module, and a shield case, each having a functional layer formed on a surface thereof.

A method for manufacturing a functional layer with information according to embodiments of the present disclosure includes a process of giving information to the functional layer while forming the functional layer on the surface of the electronic component. The functional layer with information is a layer that includes an information area having information and a non-information area other than the information area.

The “giving information to a functional layer while forming the functional layer” refers to obtaining a functional layer with information by forming an information area, which is an area to which information is given, and a non-information area, which is an area to which no information is given in the same process. For example, a functional layer with information is obtained by discharging a material to be a functional layer by liquid discharging to form an uneven shape having different thicknesses by lamination or discharging functional layer materials different from each other to form a pattern, thus forming the information area and the non-information area at one time in the same process. Since there is a color difference between the information area and the non-information area formed as described above, the information given to the information area is recognizable. The term “recognizable” refers to that information can be read by recognizing the color difference with, for example, the naked eye of human or a reading device. By contrast, for example, forming a functional layer to which no information is given to a certain thickness and then giving information to the functional layer by scraping the functional layer by a certain thickness in another step such as laser processing or etching is not included in the “giving information to a functional layer while forming the functional layer.”

In embodiments of the present disclosure, the term “Information” refers to information recognizable by human or recognizable by a machine. To be “recognizable by a machine” refers to that even a small QR® code or matrix code that is difficult to recognize with the naked eye can be recognized. In embodiments of the present disclosure, the term “information” includes graphics, letters, and numbers. Further, in embodiments of the present disclosure, the term “information” includes a code such as a QR code that does not has meaning by itself. Specifically, the “information” includes information relating to the electronic component such as a manufacturer of the electronic component, a model number of the electronic component, and a production lot number.

The functional layer with information according to embodiments of the present disclosure includes the information area and the non-information area. When the information area is formed in an uneven shape and the thickness of the functional layer with information is not uniform, production efficiency is enhanced. Preferably, the functional layer with information is made of the same material. There is a color difference between the information area and the non-information area due to the unevenness. When the information area is formed by a pattern shape and the thickness of the functional layer with information is uniform, the color of the pattern itself is different from the color of the non-information area.

### Embodiment 1

In the present embodiment, information is given to the functional layer by forming the information area into a specific shape.

Overall Configuration of Manufacturing Apparatus 100 for Functional-Layer-Provided Electronic Component 10

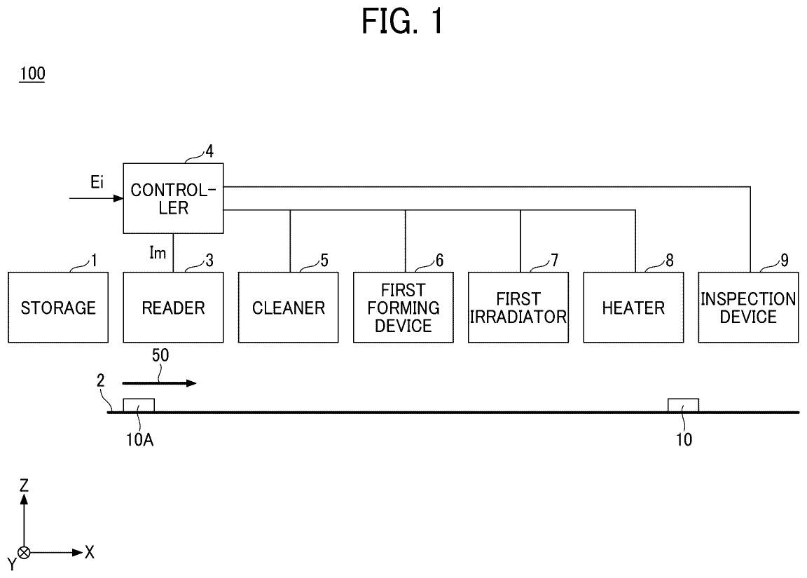

FIG. 1 is a block diagram illustrating an overall configuration of a manufacturing apparatus 100 for manufacturing a functional-layer-provided electronic component 10 according to Embodiment 1.

As illustrated in FIG. 1, the manufacturing apparatus 100 includes a storage 1, a conveyor 2, a reader 3, a controller 4, a cleaner 5, a first forming device 6, a first irradiator 7, a heater 8, and an inspection device 9.

The manufacturing apparatus 100 takes out, from the storage 1, an electronic component 10A to which forming of the functional layer has not yet performed. The conveyor 2 conveys the electronic component 10A in a conveyance direction 50. The reader 3 of the manufacturing apparatus 100 reads the conveyed electronic component 10A. The controller 4 of the manufacturing apparatus 100 determines a specific shape to be formed on the electronic component 10A and a position on the functional layer where the specific shape is to be formed, according to information Ei regarding the electronic component 10A acquired from an external device on the basis of the reading result Im by the reader 3. Subsequently, the cleaner 5 of the manufacturing apparatus 100 cleans the surfaces of the electronic components 10A. After the cleaning, the first forming device 6 discharges a liquid composition for the functional layer to form the functional layer on the surfaces of the electronic components 10A and substantially concurrently form the specific shape determined by the controller 4. Thus, information corresponding to the information Ei regarding the electronic component 10A is given to the functional layer. Subsequently, the first irradiator 7 of the manufacturing apparatus 100 irradiates the functional layer formed on the electronic component 10A with heat, laser light of various wavelengths, or ultraviolet light other than the laser light to cure the functional layer. The heater 8 heats the cured functional layer to dry the cured functional layer. As a result, the functional-layer-provided electronic component 10 is obtained. Subsequently, the inspection device 9 of the manufacturing apparatus 100 inspects, for example, the appearance, electronic characteristics, or a combination of these of the functional-layer-provided electronic component 10.

FIG. 1 illustrates the electronic component 10A and the functional-layer-provided electronic component 10, specifically illustrates that the electronic component 10A is conveyed in the conveyance direction 50, a functional layer is formed on the electronic component 10A, and then the functional layer is heated, and thus the functional-layer-provided electronic component 10 is obtained.

The storage 1 accommodates a tray in which multiple electronic components 10A are arranged. The electronic component 10A is an electronic component on which the functional layer is to be formed.

The conveyor 2 includes a belt conveyor, a roller conveyor, or a combination of these, and conveys the tray placed on the belt, the roller, or a combination of these in the conveyance direction 50. The conveyor 2 conveys the electronic component 10A accommodated in the tray in the conveyance direction 50.

The reader 3 reads the electronic component 10A. The reader 3 includes a camera including a lens and an imaging element, a line sensor, or a combination of these. For example, the reader 3 can read the electronic component 10A by capturing an image of the electronic component 10A.

The information read by the reader 3 includes, for example, a manufacturer name, a component number, a lot number, information regarding positioning, and information regarding the size of the electronic component 10A. The reader 3 may read the information printed as letters, symbols, or a combination of these on the surface of the electronic component 10A by performing image processing on the image of the electronic component 10A. The reader 3 transmits the reading result Im to the controller 4.

The controller 4 controls overall operation of the manufacturing apparatus 100. The controller 4 is communicably connected to an external device through, for example, a wired cable, a wireless network, a local area network (LAN), or the Internet.

The controller 4 acquires the information Ei regarding the electronic component 10A from the external device on the basis of the reading result Im from the reader 3. The information Ei regarding the electronic component 10A is, for example, specification information of the electronic component 10A provided by a manufacturer of the electronic component 10A. The specification information of the electronic component 10A includes, for example, a circuit diagram. The controller 4 may determine the specific shape to be formed on the electronic component 10A and the position where the specific shape is to be formed on the functional layer, on the basis of the information Ei regarding the electronic component 10A acquired from the external device. The controller 4 controls operation of, for example, the first forming device 6 and the first irradiator 7 on the basis of the determination result.

For example, after acquiring the information Ei regarding the electronic components 10A from the external device, the controller 4 performs binarization image processing on the reading result Im obtained by the reader 3. The controller 4 analyzes the position where ground (GND) lines are concentrated in the electronic component 10A on the basis of a circuit diagram of a semiconductor element contained in the information Ei regarding the electronic component 10A, and performs drawing image forming processing according to the position where many GND lines are concentrated in the electronic component 10A and the size of the semiconductor element. In the present embodiment, the drawing image forming processing refers to processing of generating a drawing image data used for forming the functional layer on the electronic component 10A by the first forming device 6 described below in detail. In the drawing image forming processing, the controller 4 determines at which position on the upper surface of the semiconductor element component the specific shape corresponding to the information Ei regarding the electronic component 10A is to be formed. The controller 4 determines the size of an area where the specific shape is to be formed in the functional layer according to the position where the specific shape is to be formed in the functional layer and the size of the semiconductor element.

The cleaner 5 cleans the electronic component 10A conveyed by the conveyor 2. The cleaning by the cleaner 5 is implemented by various cleaning methods such as air blow cleaning, pure water cleaning, solvent cleaning, infrared irradiation cleaning, heat irradiation cleaning, ultraviolet light irradiation cleaning, atmospheric pressure plasma cleaning, dry cleaning, ultraviolet light ozone cleaning, buff polishing, and blast cleaning. A suitable cleaning method can be appropriately selected according to specifications of the electronic component 10A, the specifications of the functional layer formed on the electronic component 10A, or a combination of these. The cleaner 5 dries the surface of the electronic components 10 after the cleaning.

For example, in a method for forming a functional layer with information, when information regarding an electronic component such as letters and symbols indicating a manufacturer name, a component number, a production lot number, a product type, positioning, or a combination of these is printed on the surface of the electronic component on which forming of the functional layer has not yet performed, the information printed on the surface of the electronic component is covered with the functional layer. As a result, the information printed on the surface of the electronic component cannot be recognized from the outside of the functional layer. Accordingly, when a functional-layer-provided electronic component is mounted on, for example, a PWB substrate, it may become impossible to position the functional-layer-provided electronic component, or it may become impossible to acquire tracking information of the functional-layer-provided electronic component. On the other hand, when information regarding an electronic component is given to a functional-layer-provided electronic component in a manner that the information is recognized from the outside in a different process after forming the functional layer, the number of manufacturing processes increases. This may increase the manufacturing time or the manufacturing cost due to the increase of the number of apparatuses, and thus lowering the manufacturing efficiency.

In the present embodiment, the first forming device 6 gives the information Ei to the functional layer while forming the functional layer on the surface of the electronic component 10A. The first forming device 6 gives the information Ei regarding the electronic component to the functional layer by forming the functional layer into the specific shape. The functional layer with information to which information is given is a layer including the information area including the specific shape having the information Ei and the non-information area other than the information area. There is a color difference between the information area and the non-information area. Thus, even after the functional layer is formed on the electronic component 10A, the information Ei regarding the electronic component can be recognized from the outside of the functional layer. Making the information Ei regarding the electronic component recognizable enables positioning of the functional-layer-provided electronic component, acquisition of tracking information of the functional-layer-provided electronic component, or a combination of these, when the functional-layer-provided electronic component is mounted on, for example, the PWB substrate. Further, since the formation of the functional layer and the provision of the information Ei regarding the electronic component to the functional layer are performed in the same process, increases in the number of manufacturing processes, the number of manufacturing steps, and the manufacturing cost are reduced. As a result, in the present embodiment, a method for forming a functional layer with information is provided with excellent manufacturing efficiency. Furthermore, in the present embodiment, since the information area and the non-information area are formed in the same layer, a method for forming a functional layer with information area is provided, which contributes to further miniaturization and reduction in height of an electronic component, an electronic module, or a combination of these.

In the present embodiment, the first forming device 6 may form the functional layer on the electronic component 10A and give information to the functional layer by discharging a liquid composition for the functional layer. Preferably, the first functional layer having a specific three-dimensional shape is formed by discharging the liquid composition and changing the discharge amount or the number of times of lamination of the liquid composition. Accordingly, since the functional layer can be formed in various shapes, various information can be given to the functional layer in various forms. In particular, when an inkjet is used for the liquid discharge, detailed and clear information can be given. Further, compared to a case in which a specific shape is formed by scraping a functional layer that is formed to have a uniform thickness, the production efficiency is enhanced, and waste of the functional layer forming material is prevented.

In the present embodiment, the first forming device 6 discharges an insulating material as the liquid composition according to the present embodiment. For example, IJSR4000 manufactured by Taiyo Ink Mfg. Co., Ltd. can be used as the insulating material. However, the method for forming the functional layer by the first forming device 6 is not limited to discharging the liquid composition. Alternatively or additionally, a method using a spray, a dispenser, a die coater, or pull-up coating may be applied. Further, the information given to the functional layer is not limited to the information Ei regarding the electronic component. The information given to the functional layer may include information regarding a manufacturing process or a manufacturing site.

In the present embodiment, the first forming device 6 may discharge the liquid composition with a line head system. The line head system refers to a system in which the liquid composition is discharged from the first forming device 6 having a length equivalent to the entire width of one or more electronic components 10A placed on the tray in a direction substantially orthogonal to the conveyance direction 50. By using the line head system, liquid to applied to a wide area on one or more electronic components 10A at one time. Thus, the manufacturing can be speeded up. The discharge by the first forming device 6 is not limited to the line head system. Alternatively, the first forming device 6 may discharge the liquid composition by, for example, a serial head system.

In the present embodiment, the information given to the functional layer by the first forming device 6 may include one or more types selected from the group consisting of alphanumeric characters, a barcode, and a two-dimensional code corresponding to the information regarding the electronic component. With this configuration, the information Ei regarding the electronic component can be managed as digital information that can be easily read.

In the present embodiment, the first forming device 6 may discharge a liquid composition containing a polymerizable compound. By discharging the liquid composition containing the polymerizable compound, the liquid composition can be cured by irradiation with an active energy ray from the first irradiator 7 described below. Alternatively, the first forming device 6 may discharge a liquid composition other than the polymerizable compound, or may discharge a liquid composition curable by an active energy ray other than ultraviolet light.

The first irradiator 7 irradiates the functional layer formed by the first forming device 6 on the electronic component 10A with ultraviolet light as an active energy ray. The irradiation with ultraviolet light by the first irradiator 7 cures the liquid composition forming the functional layer, and thus the functional layer is cured. In the present embodiment, the liquid composition discharged by the first forming device 6 includes the polymerizable compound, and the process of irradiating the functional layer formed on the electronic component 10A with ultraviolet light is included. With this configuration, the time for curing the functional layer is shortened and the manufacturing time of the functional-layer-provided electronic component 10 is shortened. However, the irradiating with heat may be used, in addition to or in alternative to the irradiation with ultraviolet light.

The heater 8 heats the functional-layer-provided electronic component 10 in which the functional layer on the electronic component 10A is cured. By the heating, the functional layer in the functional-layer-provided electronic component 10 is cured and dried, and thus fixed.

The inspection device 9 inspects the appearance, electrical characteristics, or a combination of these of the functional-layer-provided electronic component 10 in which the functional layer is fixed. For example, the inspection device 9 inspects a defect in the appearance of the functional-layer-provided electronic component 10 by performing image processing on an image of the functional-layer-provided electronic component 10 captured by the camera. Alternatively, the inspection device 9 inspects the electrical characteristics of the functional-layer-provided electronic component 10 by performing an energization inspection using, for example, an electric circuit having a tester function.

Configuration of Controller 4

Hardware Configuration

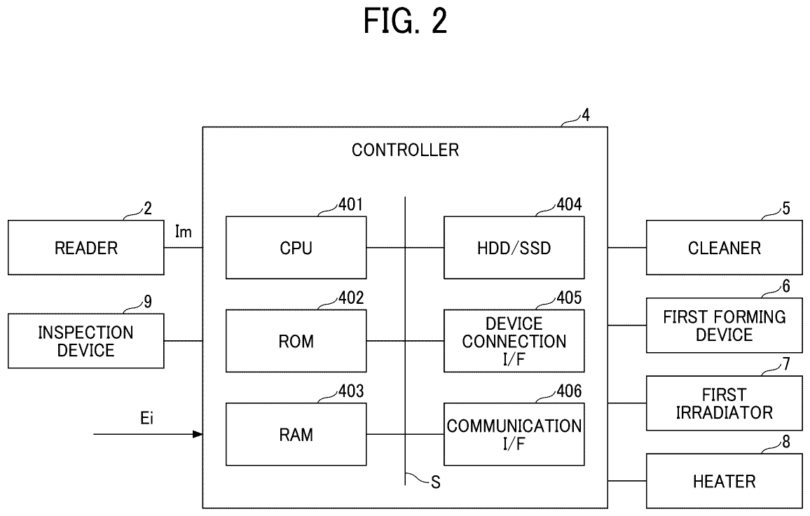

FIG. 2 is a block diagram illustrating a hardware configuration of the controller 4 according to embodiments of the present disclosure. The controller 4 is implemented by a computer. The controller 4 includes a central processing unit (CPU) 401, a read only memory (ROM) 402, and a random access memory (RAM) 403. The controller 4 further includes a hard disk drive (HDD)/solid state drive (SSD) 404, a device connection interface (I/F) 405, and a communication I/F 406. These components are communicably connected to each other through a system bus S.

The CPU 401 performs control processing including various kinds of arithmetic and logic processing. The ROM 402 stores programs such as an initial program loader (IPL) to boot the CPU 401. The RAM 403 is used as a work area for the CPU 401. The HDD/SSD 404 stores various kinds of information such as programs. The device connection I/F 405 is an interface that connects the controller 4 to various devices. The communication I/F 406 is an interface that enables communication between the controller 4 and an external device such as an external personal computer (PC) through a communication network.

Functional Configuration

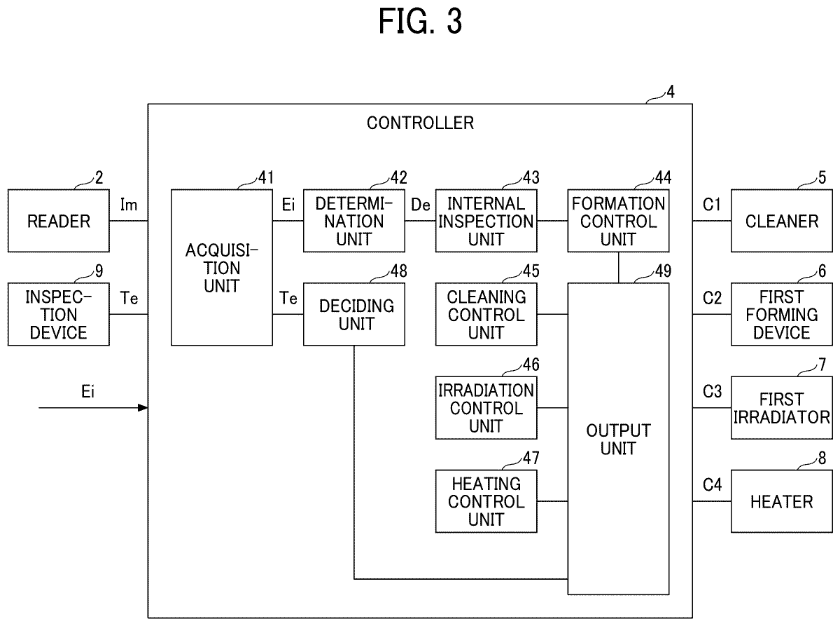

FIG. 3 is a block diagram illustrating a functional configuration of the controller 4 according to embodiments of the present disclosure. The controller 4 includes an acquisition unit 41, a determination unit 42, an internal inspection unit 43, a formation control unit 44, a cleaning control unit 45, an irradiation control unit 46, a heating control unit 47, a deciding unit 48, and an output unit 49.

The functions of the determination unit 42, the internal inspection unit 43, the formation control unit 44, the cleaning control unit 45, the irradiation control unit 46, the heating control unit 47, and the deciding unit 48 are implemented by a processor such as the CPU 401 illustrated in FIG. 2 executing processing defined in a program stored in a nonvolatile memory such as the ROM 402. The functions of the acquisition unit 41 and the output unit 49 are implemented by the device connection I/F 405 and the communication I/F 406 illustrated in FIG. 2.

The acquisition unit 41 controls communication with the reader 3 to acquire the reading result Im from the reader 3. Further, the acquisition unit 41 controls communication with the external device to acquire the information Ei regarding the electronic component 10A from the external device on the basis of the reading result Im. Furthermore, the acquisition unit 41 controls communication with the inspection device 9 to acquire inspection information Te of the functional-layer-provided electronic component 10 from the inspection device 9. The acquisition unit 41 outputs the acquired information Ei regarding the electronic component 10A to the determination unit 42, outputs the reading result Im to the internal inspection unit 43, and outputs the inspection information Te to the internal inspection unit 43.

The determination unit 42 determines, on the basis of the reading result Im, the specific shape of the functional layer to be formed on the electronic component 10A and a position on the functional layer where the specific shape is to be formed, on the basis of the information Ei regarding the electronic component 10A acquired from the external device by the acquisition unit 41. The determination unit 42 outputs image data De as the determination result to the internal inspection unit 43.

The internal inspection unit 43 detects a defect in the image data De determined by the determination unit 42 to internally inspect whether the image data De is an acceptable product. For example, when the information given to the functional layer by the first forming device 6 includes a two-dimensional code such as a QR code corresponding to the information Ei regarding the electronic component 10A, the internal inspection unit 43 detects a defect in the two-dimensional code. When no defect is detected, the internal inspection unit 43 outputs the image data De as an acceptable product to the formation control unit 44. By contrast, when any defect is detected, the internal inspection unit 43 does not output the image data De, which is a rejected product, to the formation control unit 44, and outputs information on the defect to an external device such as a display via the output unit 49.

The formation control unit 44 outputs a discharge control signal C2 to the first forming device 6 via the output unit 49 on the basis of the image data De as the determination result by the determination unit 42, to control the discharge operation of liquid composition by the first forming device 6.

The cleaning control unit 45 outputs a cleaning control signal C1 to the cleaner 5 via the output unit 49 to control operation of the cleaner 5 such as the start or stop of cleaning by the cleaner 5.

The irradiation control unit 46 outputs an irradiation control signal C3 to the first irradiator 7 via the output unit 49 to control operation of the first irradiator 7 such as the start of irradiation of ultraviolet light by the first irradiator 7, i.e., the lighting of the ultraviolet light, the stop of irradiation of ultraviolet light, and the light intensity of the ultraviolet light.

The heating control unit 47 outputs a heating control signal C4 to the heater 8 via the output unit 49 to control operation of the heater 8 such as the start or stop of heating by the heater 8.

The deciding unit 48 determines whether the manufactured functional-layer-provided electronic component 10 is an acceptable product on the basis of the inspection information Te from the inspection device 9, and outputs the determination result to an external device such as a display via the output unit 49.

Manufacturing Method of Functional-Layer-Provided Electronic Component 10

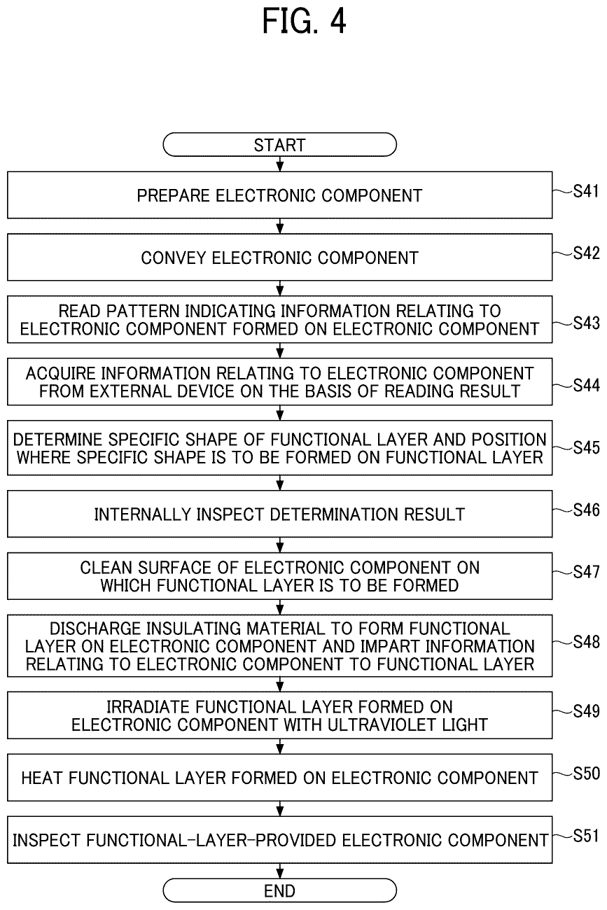

FIG. 4 is a flowchart of a method for manufacturing the functional-layer-provided electronic component 10, according to the present embodiment.

First, in step S41, a process of preparing the electronic component 10A on which the functional layer is not yet formed is performed. The storage 1 accommodates the tray in which multiple prepared electronic components 10A are arranged.

Subsequently, in step S42, the conveyor 2 of the manufacturing apparatus 100 conveys the tray in which the electronic components 10A are accommodated. Thus, the electronic components 10A are conveyed in the conveyance direction.

Subsequently, in step S43, the reader 3 of the manufacturing apparatus 100 performs a process of reading the electronic component 10A. The reader 3 reads, for example, a manufacturer name, a component number, a lot number, information regarding positioning, and information regarding the size of the electronic component 10A printed on the surface of the electronic component 10A, and outputs the reading result Im to the controller 4.

Subsequently, in step S44, the manufacturing apparatus 100 performs a process of acquiring information Ei regarding the electronic component 10A from an external device. Specifically, the manufacturing apparatus 100 refers to the external device on the basis of the reading result obtained by the reader 3, to acquire the information Ei regarding the electronic component. In the example illustrated in FIG. 4, as the process of acquiring the information Ei regarding to the electronic component 10A, both the process in step S43 of reading the electronic component 10A by the reader 3 and the process in step S44 of acquiring the information regarding the electronic component 10A from the external device are performed.

Subsequently, in step S45, the controller 4 of the manufacturing apparatus 100 performs a process of determining the specific shape and the position where the specific shape is formed on the functional layer, on the basis of the information Ei regarding the electronic component 10A acquired in step S44.

Subsequently, in step S46, the internal inspection unit 43 of the controller 4 of the manufacturing apparatus 100 internally inspects the image data De as the determination result in step S45. When no defect is detected, the internal inspection unit 43 outputs the image data De as an acceptable product to the formation control unit 44. When any defect is detected, the internal inspection unit 43 outputs information regarding the detected defect to an external device such as a display via the output unit 49.

Subsequently, in step S47, the cleaner 5 of the manufacturing apparatus 100 cleans the surface of the electronic component 10A on which the functional layer is to be formed.

Subsequently, in step S48, the manufacturing apparatus 100 performs a process of forming a functional layer on the electronic component 10A and giving information to the functional layer. Specifically, the first forming device 6 forms the functional layer on the electronic component 10A and also gives the information Ei regarding the electronic component to the functional layer by discharging an insulating material or the conductive material on the basis of the image data De as the determination result in step S45. The functional layer to which with the information Ei is given corresponds to the functional layer with information according to the present embodiment.

Subsequently, in step S49, the first irradiator 7 of the manufacturing apparatus 100 performs a process of irradiating the functional layer formed on the electronic component 10A with ultraviolet light or heat.

Subsequently, in step S50, the heater 8 of the manufacturing apparatus 100 heats the functional layer formed on the electronic component 10A.

For example, when the target thickness of the functional layer is thick, in order to stack functional layers made of an insulating material, after forming one functional layer, the one functional layer is temporarily cured by irradiation with spot ultraviolet light at, for example, an intensity of 1293 (mJ/cm²). The temporary curing operation is repeated for multiple layers, thus a functional layer having a total layer thickness of about 20 μm is formed. Main curing processing is perfumed on the functional layer thus formed at 150° C. for thirty minutes.

Subsequently, in step S51, the inspection device 9 of the manufacturing apparatus 100 inspects the functional-layer-provided electronic component 10 obtained as a result of forming the functional layer on the electronic component 10A.

As described above, the functional layer with information according to the present embodiment is formed on the electronic component 10A, and thus the functional-layer-provided electronic component 10 is manufactured.

Examples of Functional-Layer-Provided Electronic Component According to Embodiment

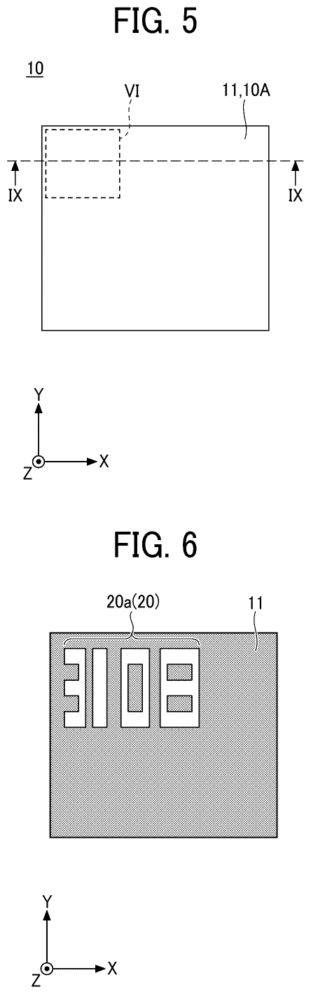

The functional-layer-provided electronic component 10 according to the present embodiment is described with reference to FIG. 5 to FIG. 20.

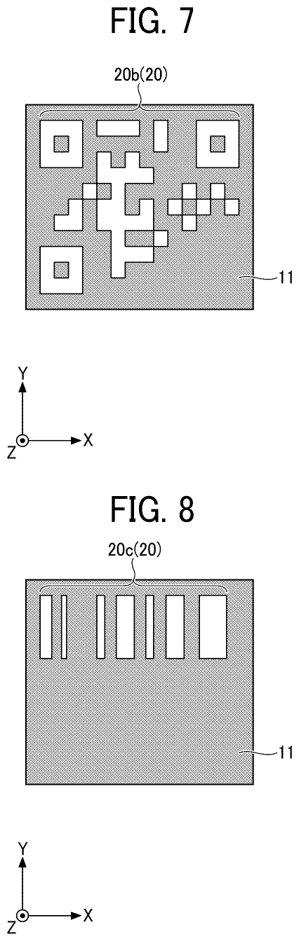

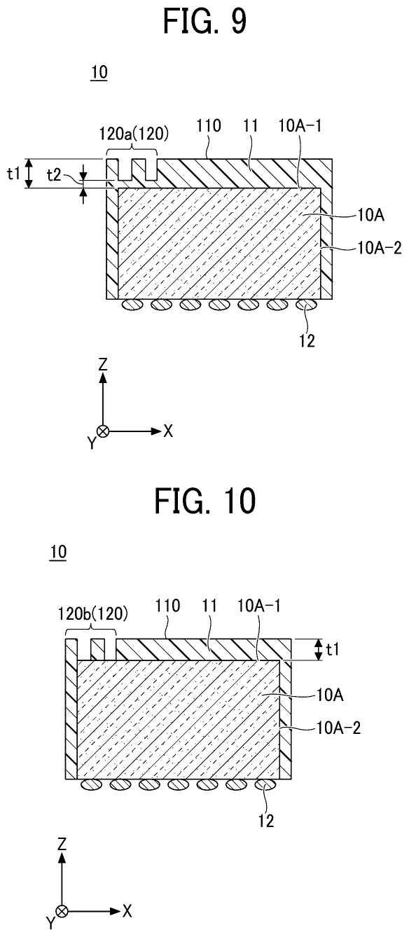

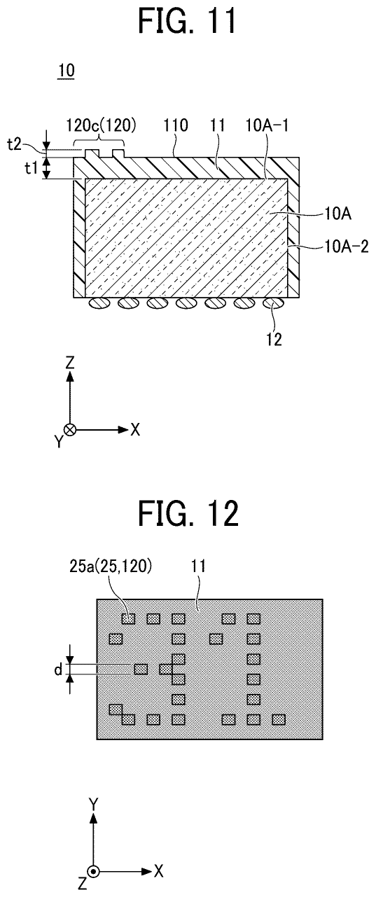

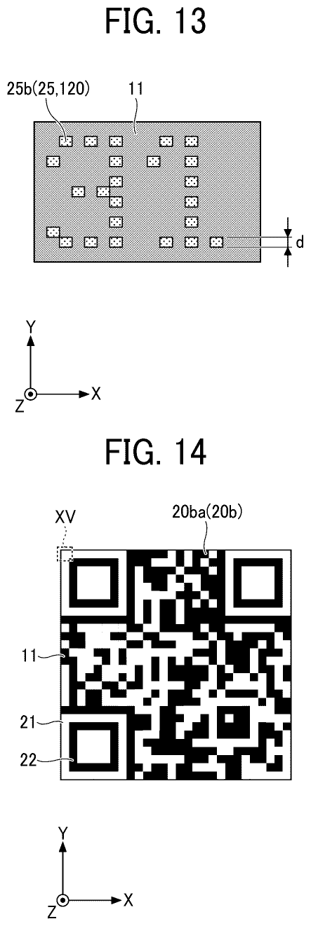

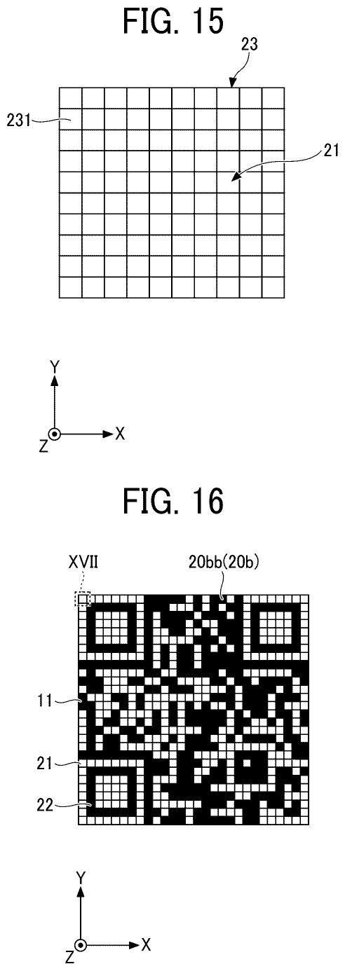

FIG. 5 is a schematic top view of an example of the functional-layer-provided electronic component 10 manufactured by the manufacturing method according to the present embodiment. FIG. 6 to FIG. 8 are enlarged top views of an area VI in FIG. 5. FIG. 6 illustrates a first example, FIG. 7 illustrates a second example, and FIG. 8 illustrates a third example. FIG. 9 to FIG. 11 are cross-sectional views taken through a line IX-IX of FIG. 5. FIG. 9 illustrates a first example, FIG. 10 illustrates a second example, and FIG. 11 illustrates a third example. FIG. 12 and FIG. 13 are top views of a dot 25 indicating information given to a functional layer 11. FIG. 12 illustrates a first example, and FIG. 13 illustrates a second example. FIG. 14 is a top view of a first example of a QR code 20b given to the functional layer 11. FIG. 15 is an enlarged top view of an area XV in FIG. 14.

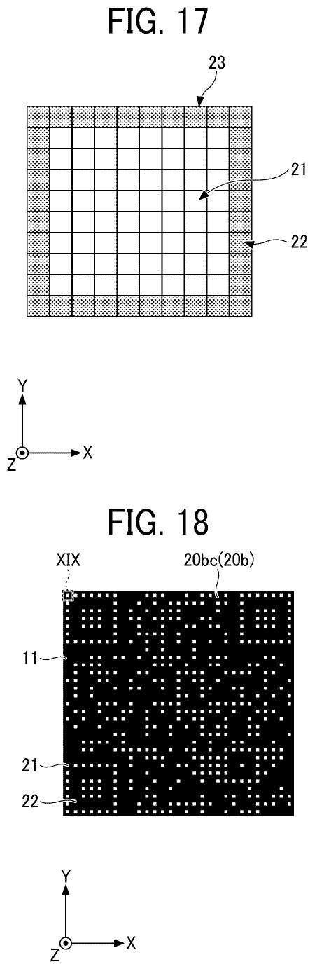

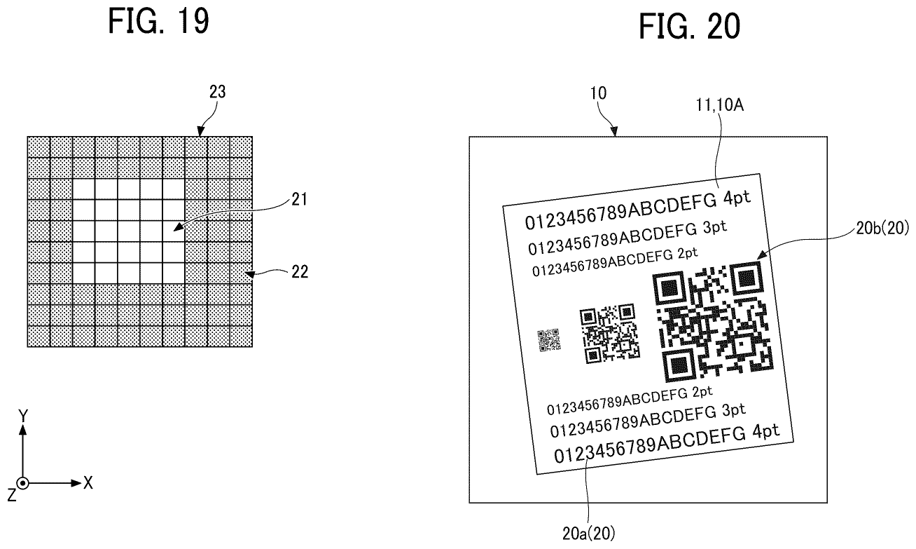

FIG. 16 is a top view of a second example of the QR code 20b given to the functional layer 11. FIG. 17 is an enlarged top view of an area XVII in FIG. 16. FIG. 18 is a top view of a third example of the QR code 20b given to the functional layer 11. FIG. 19 is an enlarged top view of an area XIX in FIG. 18. FIG. 20 is a top view of an example of the functional-layer-provided electronic component 10 manufactured by the manufacturing method according to the present embodiment. The functional layer 11 corresponds to a functional layer with information according to embodiments of the present disclosure.

FIG. 5 schematically illustrates the functional layer 11 formed on the upper surface of the electronic component 10A. In FIG. 5, since the functional layer 11 and the electronic component 10A overlap, the reference numeral for the functional layer 11 and the reference numeral for the electronic component 10A are illustrated side by side. In the following description, when objects overlap, the reference numerals representing the objects may be illustrated side by side, in substantially the same manner as FIG. 5.

In the present embodiment, information 20 such as the information Ei regarding the electronic component 10A is given to an information area VI, which is a part of the functional layer 11. FIG. 6 to FIG. 8 illustrate the information 20 given to the area VI. In the example illustrated in FIG. 6, a number 20a of “3108” is given as the information 20. In the example illustrated in FIG. 7, the QR code 20b as a two-dimensional code is given as the information 20. In the example illustrated in FIG. 8, a barcode 20c is given as the information 20.

The information given to the functional layer 11 is given by forming the specific shape in the information area VI of the functional layer 11. FIG. 9 to FIG. 11 each illustrates a specific shape 120 formed in the functional layer 11. In the examples illustrated in FIG. 9 to FIG. 11, the functional layer 11 is formed on an upper surface 10A-1 and a side surface 10A-2 of the electronic component 10A. In the present disclosure, “on the electronic component 10A” refers to on the surfaces of the electronic component 10A including the upper surface 10A-1 of the electronic component 10A and the side surface 10A-2 of the electronic component 10A. A terminal 12 is a terminal that electrically connects the electronic component 10A to, for example, a PCB substrate.

In the present embodiment, the specific shape 120 may include at least one of a recess 120a that is recessed relative to the non-information area 110 in which the specific shape 120 is not formed in the functional layer 11, a protrusion 120c that protrudes relative to the non-information area 110, or a hole 120b that penetrates the functional layer 11 in the thickness direction of the functional layer 11. In the example illustrated in FIG. 9, the recess 120a is formed as the specific shape 120. In the example illustrated in FIG. 10, the hole 120b is formed as the specific shape 120. In the example illustrated in FIG. 11, the protrusion 120c is formed as the specific shape 120. The information 20 such as the number 20a, the QR code 20b, and the barcode 20c is given to the functional layer 11 by forming the specific shape 120 such as the recess 120a, the hole 120b, or the protrusion 120c in the functional layer 11, or by forming a combination thereof in the functional layer 11.

In the present embodiment, on the basis of the information Ei regarding the electronic component 10A, the specific shape 120 corresponding to the information such as letters, numbers, a bar code, and a two-dimensional code including the information Ei regarding the electronic component 10A may be formed at a position where the GND lines are concentrated in the electronic component 10A. The position of the area VI in FIG. 5 corresponds to the position where the GND lines are concentrated in the electronic component 10A.

For example, the formation of the specific shape 120 in functional layer 11 may cause the functional layer 11 to get thinner or cause the area of the functional layer 11 to get smaller than the non-information area 110. As a result, the accuracy of shielding electromagnetic waves and noise may degrade, compared with the non-information area 110. In the present embodiment, in the electronic component 10A, the specific shape 120 is formed at a position where the GND lines with less oscillation of electromagnetic waves and noise are concentrated, and thus degradation in the shielding accuracy of the functional layer 11 due to the formation of the specific shape 120 is reduced.

In the present embodiment, as illustrated in FIG. 9 to FIG. 11, the minimum thicknesses t2 of the functional layer 11 in the specific shape 120 may be one tenth or less of the minimum thicknesses t1 of the functional layer 11 in the non-information area 110. For example, the minimum thickness of the functional layer 11 in the non-information area 110 may be 0.1 μm or more and 30 μm or less. By so doing, the reflection state of light in the specific shape 120 and the reflection state of light in the non-information area 110 are made different. As a result, when the functional layer 11 is viewed from the outside, the color shading, hue, or a combination of these are made different between the information area including the specific shape 120 and the non-information area 110. Thus, the information 20 that is given by forming the functional layer 11 into the specific shape 120 can be suitably recognized from the outside. The relation between the thicknesses t2 of the functional layer 11 in the specific shape 120 and the thicknesses t1 in the non-information area 110 may be any other suitable one than the above-described one, provided that the information 20 can be recognized. Further, from the viewpoint of enhancing the recognizability of the information given by the specific shape 120, the color difference between the information area including the specific shape 120 and the non-information area 110 is preferably ΔE of 6.5 or more.

In the present embodiment, as illustrated in FIG. 12 and FIG. 13, the specific shape 120 may include an aggregate of dots 25. Further, the maximum widths of the dots 25 viewed from the thickness direction (Z-direction) of the functional layer 11 may be 0.5 mm or less. In FIG. 12, the specific shape 120 includes an aggregate of dots 25a. The maximum width d of the dot 25a is 0.5 mm or less. In FIG. 13, the specific shape 120 includes an aggregate of dots 25b. The maximum width d of the dot 25b is 0.5 mm or less. The dots 25a and the dots 25b have different depths in the thickness direction of the functional layer 11. Due to the difference in depth, the density, hue, or a combination of these of the color of the dots 25 are perceived to be different.

For example, in a case where the functional layer 11 is an electromagnetic wave shielding layer, the specific shape 120 includes the aggregate of the dots 25, and thus reducing the usage amount of a conductive material used, compared to a case where the specific shape includes a continuous pattern. Further, by making the maximum widths d of the dots 25 viewed from the thickness direction (Z-direction) of the functional layer 11 to 0.5 mm or less, the usage amount of the conductive material can be further reduced. Since Ag or Cu, which is a conductive material, is expensive, the cost of the functional-layer-provided electronic component 10 can be reduced by reducing the usage amount of the conductive material.

FIG. 14 to FIG. 18 illustrate the QR code 20b formed on the functional layer 11. For example, the controller 4 illustrated in FIG. 2 creates image data corresponding to the QR code 20b using general-purpose QR code creation software on the basis of the reading result Im obtained by the reader 3. The QR code 20b includes information based on the reading result Im and position information indicating a position where the QR code 20b is to be formed on the functional layer 11. The thickness of the functional layer 11 is, for example, 20 μm. The thickness of the specific shape 120 corresponding to the QR code 20b is, for example, 4 μm.

In the present embodiment, the specific shape 120 corresponding to the QR code 20b may include a first area 21 and a second area 22 in which the functional layer 11 is thinner than the first area 21. In one cell 23 of multiple cells 23 included in the specific shape 120 corresponding to the QR code 20b, the area of the second area 22 when viewed from the upper surface direction of the functional layer 11 may be one fourth or more of the area of one cell 23 when viewed from the upper surface direction of the functional layer 11.

FIG. 14 illustrates a QR code 20ba of a case where there is no second area 22 in one cell 23, in other words, there is no blank area to which no coating is applied. FIG. 15 is an enlarged view of one cell 23 corresponding to the area XV in FIG. 14. One cell 23 has a square shape when viewed from the upper surface direction of the functional layer 11. One cell 23 is constructed by multiple pixels 231 arranged two-dimensionally. In the QR code 20ba illustrated in FIG. 14 and FIG. 15, the area of the first area 21 is equal to the area of one cell 23.

FIG. 16 illustrates a QR code 20bb of a case where the area of the second area 22 in one cell 23 is substantially one fourth of the area of one cell 23. FIG. 17 is an enlarged view of one cell 23 corresponding to the area XVII in FIG. 16. In the QR code 20bb illustrated in FIG. 16 and FIG. 17, the area of the second area 22 is substantially one fourth of the area of one cell 23.

FIG. 18 illustrates a QR code 20bc of a case where the area of the second area 22 in one cell 23 is substantially one half of the area of one cell 23. FIG. 19 is an enlarged view of one cell 23 corresponding to the area XIX in FIG. 18. In the QR code 20bc illustrated in FIG. 18 and FIG. 19, the area of the second area 22 is substantially one half of the area of one cell 23.

The electromagnetic shielding effect is lost unless the opening (width) of the through hole in printing such as production of a QR code is 0.5 mm or less. Since a conductive material forming the electromagnetic wave shield is as expensive as 600,000 JPY/liter, it is preferable to increase the area of the opening as much as possible to reduce the material cost even in the printing production in the functional layer. To prevent the degradation of the shielding effect, the amount of the conductive material used for the shield can be reduced by making the opening (width) of the through hole as wide as possible, for example, 0.5 mm or less.

As described above, in one cell 23 of multiple cells 23 included in the specific shape 120 corresponding to the QR code 20b, by making the area of the second area 22 viewed from the upper surface direction of the functional layer 11 to one fourth or more of the area of the one cell 23 viewed from the upper surface direction of the functional layer 11, the usage amount of a conductive material can be reduced. Thus, the cost of the functional-layer-provided electronic component 10 is reduced.

FIG. 20 illustrate the functional-layer-provided electronic component 10 having the functional layer 11 formed on the electronic component 10A. To the functional layer 11, the number 20a and the QR code 20b are given, which are given by forming the functional layer 11 into the specific shape 120.

### Embodiment 2

A method for forming a functional layer with information is described below, according to Embodiment 2. In the description given below with reference to the drawings, like reference signs denote like elements and components, and overlapping description may be simplified or omitted as appropriate.

The present embodiment is different from Embodiment 1 in that the functional layer 11 is formed using a conductive material, and further includes a process of forming a protective layer on the functional layer 11 formed on the electronic component 10A.

Overall Configuration of Manufacturing Apparatus 100a

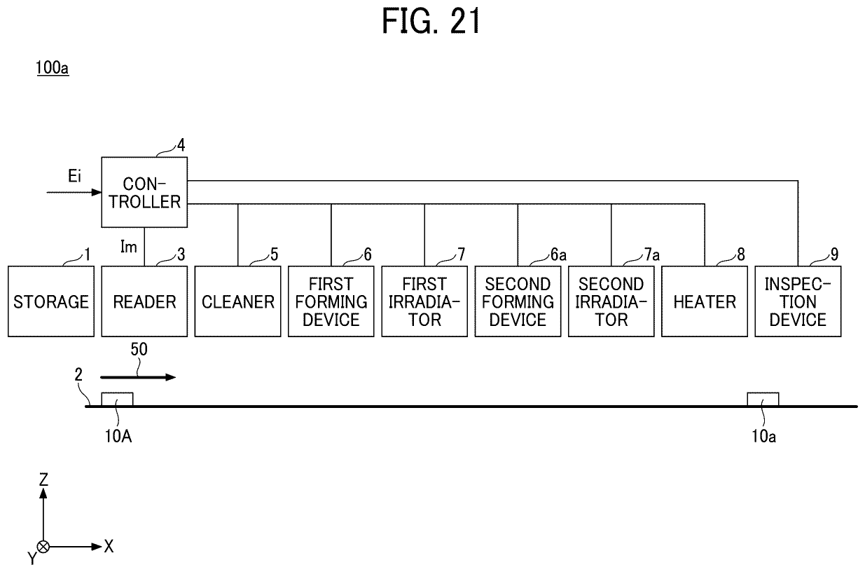

FIG. 21 is a block diagram illustrating an overall configuration of a manufacturing apparatus 100a for manufacturing a functional-layer-provided electronic component 10a according to Embodiment 2. The manufacturing apparatus 100a includes a second forming device 6a and a second irradiator 7a. The functional-layer-provided electronic component 10a has a protective layer further formed on the functional layer 11 formed on the electronic component 10A.

The second forming device 6a is disposed on downstream from the first irradiator 7 in the conveyance direction 50. The second forming device 6a forms a protective layer on the functional layer 11, which is formed on the electronic component 10A by the first forming device 6 and irradiated with the ultraviolet light by the first irradiator 7. In a case that the manufacturing apparatus 100a does not include the first irradiator 7, the second forming device 6a may be disposed on downstream from the first forming device 6 in the conveyance direction 50.

The second irradiator 7a is disposed on downstream from the second forming device 6a in the conveyance direction 50. The second irradiator 7a irradiates the protective layer that is formed on the functional layer 11 by the second forming device 6a with ultraviolet light to cure the protective layer. In a case that a liquid composition forming the functional layer 11 is not a polymerizable compound, the second irradiator 7a may be omitted in the manufacturing apparatus 100a.

Manufacturing Method of Functional-Layer-Provided Electronic Component 10a

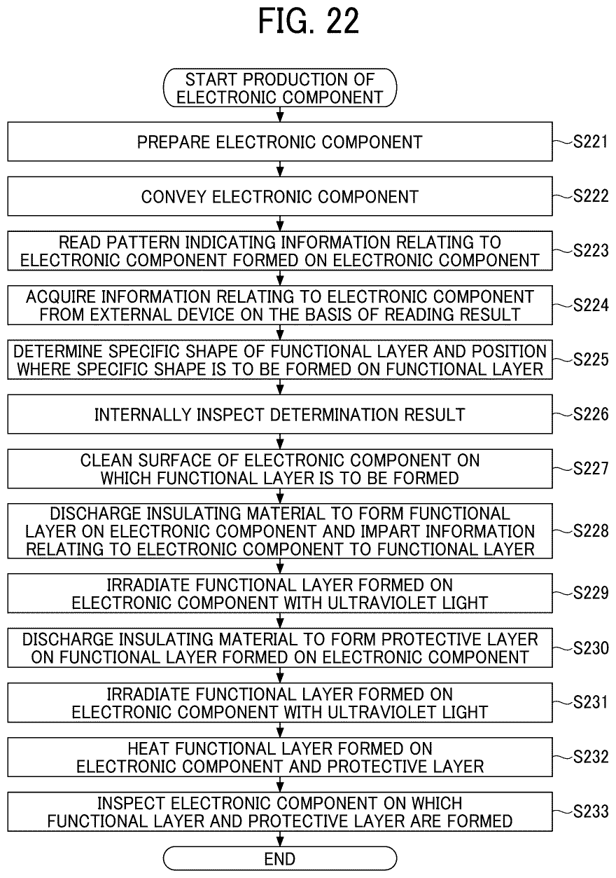

FIG. 22 is a flowchart of a method for manufacturing the functional-layer-provided electronic component 10a, according to Embodiment 2. Processes from step S221 to step S227 in FIG. 22 are performed in the same or substantially the same manner as described above referring to step S41 to step S47 of FIG. 4, and the redundant descriptions are omitted.

In step S228, the manufacturing apparatus 100a performs a process of forming the functional layer 11 on the electronic component 10A and giving information to the functional layer 11. Specifically, the first forming device 6 forms the functional layer 11 on the electronic component 10A and also gives the information Ei regarding the electronic component to the functional layer 11 by discharging a conductive material on the basis of the image data De as the determination result in step S225. For example, the thickness of the functional layer 11 is 1.5 μm, and the thickness of the specific shape 120 is 0.1 μm.

Subsequently, in step S229, the first irradiator 7 of the manufacturing apparatus 100a performs a process of irradiating the functional layer formed on the electronic component 10A with ultraviolet light.

Subsequently, in step S230, the manufacturing apparatus 100a performs a process of forming a protective layer on the functional layer 11 formed on the electronic component 10A. Specifically, the second forming device 6a forms the protective layer on the functional layer 11 formed on the electronic component 10A by discharging an insulating material. The protective layer is formed on the entire functional layer 11 including the specific shape 120.

For example, various resin materials can be used as the insulating material forming the protective layer. For example, IJSR4000 manufactured by Taiyo Ink Mfg. Co., Ltd. can be used as the insulating material. The protective layer is formed to have the thickness of, for example, 3 μm or more.

Subsequently, in step S231, the second irradiator 7a of the manufacturing apparatus 100a performs a process of irradiating the protective layer formed on the electronic component 10A with ultraviolet light or heat.

Subsequently, in step S232, the heater 8 of the manufacturing apparatus 100a heats the functional layer 11 and the protective layer, which are formed on the electronic component 10A. For example, main curing can be performed by heating the functional layer 11 and the protective layer at 150° C. for 30 minutes.

Subsequently, in step S233, the inspection device 9 of the manufacturing apparatus 100a inspects the functional-layer-provided electronic component 10 obtained as a result of forming the protective layer on the functional layer 11 on the electronic component 10A.

Thus, the functional-layer-provided electronic component 10a is manufactured.

In the present embodiment, the functional layer 11 is formed using the conductive material, and the method further includes a process of forming the protective layer on the functional layer 11 formed on the electronic component 10A. Thus, since the functional layer 11 formed of the conductive material is covered with the protective layer, corrosion, oxidation, and sulfurization of the functional layer 11 can be reduced. The present embodiment further provides effects similar to those provided by Embodiment 1 described above.

The protective layer according to the present embodiment can also be applied to Embodiment 3 described below.

### Embodiment 3

Embodiment 3 is different from Embodiment 1 in that information is given by forming the information area into a specific pattern shape using a material different from a material forming the non-information area or using the same material as the material forming the non-information area under different forming conditions. The functional-layer-provided electronic component according to the present embodiment has a functional layer formed on the surface of the electronic component. The functional layer is a layer including the information area and the non-information area, the entire functional layer has a uniform thickness. Information is given to the information area by a pattern shape having a color difference different from the non-information area. From the viewpoint of enhancing the recognizability of the information, the color difference between the information area and the non-information area is preferably ΔE of 6.5 or more.

In the present embodiment, the information area and the non-information area may be formed of a conductive material or a non-conductive material. The conductive material is appropriately determined according to a function required for the functional layer. The information area having the specific pattern shape and the non-information area may be formed of a conductive material, and the information area and the non-information area may be formed of the same conductive material or different conductive materials. The “same conductive material” according to the present embodiment refers to a conductive material that is the same kind of, for example, metal or alloy, miniatured by the same manufacturer and of the same type. In other words, “the same conductive material” according to the present embodiment refers to a conductive material that is identical in all aspects. By configuring the information area and the non-information area with the same conductive material, the efforts and material cost required for managing multiple conductive materials of different kinds are reduced, compared to a case of using different conductive materials. In a case where at least the same conductive material is used, the information area and the non-information area have to be formed to have different colors by forming the areas under different formation conditions, such as different firing conditions. On the other hand, the “different conductive materials” refer to conductive materials of different kinds of, for example, metal or alloy as well as conductive materials of the same kind of, for example, metal or alloy and different types. In other words, the “different conductive materials” include materials having different colors originally and materials that emit different colors under the same firing conditions.

A functional-layer-provided electronic component 10b according to the present embodiment is described below in detail.

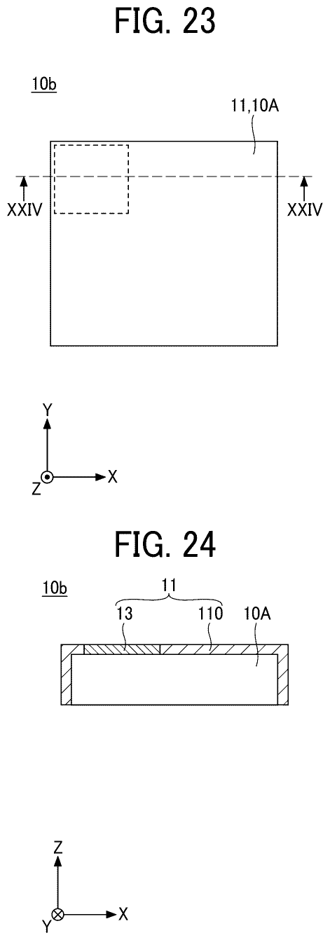

FIG. 23 and FIG. 24 are views of an example of a configuration of the functional-layer-provided electronic component 10b, according to the present embodiment. FIG. 23 is a top view of the functional-layer-provided electronic component 10b. FIG. 24 is a cross-sectional view taken through a line XXIV-XXIV of FIG. 23. As illustrated in FIG. 23 and FIG. 24, the functional-layer-provided electronic component 10b includes the electronic component 10A and the functional layer 11. The functional layer 11 includes a pattern shape 13 as the information area and the non-information area 110. The functional layer 11 is a layer formed on the upper surface and the side surface of the electronic component 10A.

### First Example

In a first example, the information is provided by forming the information area into a specific pattern shape with a material different from a material forming the non-information area.

For example, Ag nano ink of DNS-0169I manufactured by Daicel Corporation can be used for the non-information area 110. Daicel Corporation corresponds to the manufacturer of the conductive material, and DNS-0169I corresponds to the type. For the pattern shape 13, Ag nano ink of I40DM-106 manufactured by Pv Nano Cell Ltd. can be used. Pv Nano Cell Ltd. corresponds to the manufacturer of the conductive material and I40DM-106 corresponds to the type. In other words, the “different conductive materials” are used, since the non-information area 110 and the pattern shape 13 are formed of conductive materials of the same metal type but different types. Materials used for the non-information area 110 and the pattern shape 13 can be changed appropriately, provided that they have different colors.

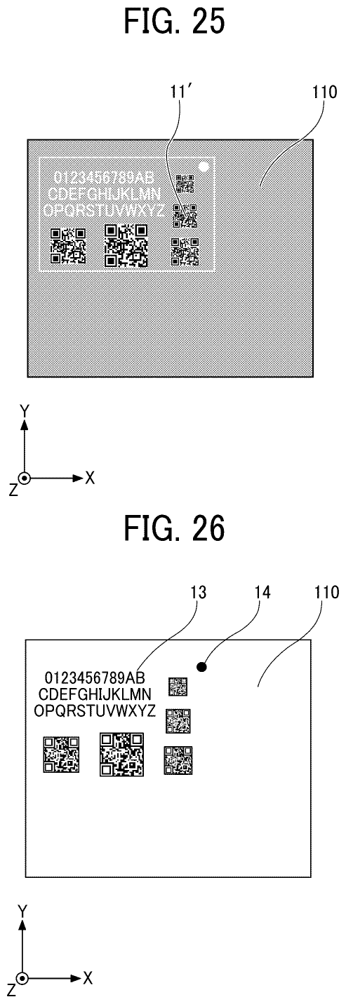

The functional layer 11 can be formed on the electronic component 10A by inkjet. FIG. 25 and FIG. 26 are views of an example of a process of forming the functional layer 11 on the electronic component 10A. FIGS. 25 and 26 are top views of the functional-layer-provided electronic component 10b.

FIG. 25 illustrates the electronic component 10A to which the non-information area 110 is given. In FIG. 25, a black area indicates the non-information areal 10 in which the Ag nano ink for the functional layer 11 is applied on the electronic component 10A. A blank area 11′, which is not filled in black, is an area to which the pattern shape 13 is to be given in the next process.

FIG. 26 illustrates the electronic component 10A to which the Ag nano ink for the pattern shape 13 is applied to the blank area 11′ of FIG. 25. In FIG. 26, the non-information area 110 given to the electronic component 10A is illustrated in white, and the pattern shape 13 given to the blank area 11′ is illustrated in black.

The above-described order of giving the non-information area 110 and giving the pattern shape 13 may be appropriately changed.

After the non-information area 110 and the pattern shape 13 are given on the electronic component 10A, the functional layer 11 is formed on the electronic component 10A by firing the non-information area 110 and the pattern shape 13.

In the present embodiment, the pattern shape 13 may include a figure that indicates information regarding the position of a pin provided in the functional-layer-provided electronic component 10b. The FIG. 14 in FIG. 26 corresponds to a figure indicating the position of such a reference pin.

### Second Example

A second example is different from the first example in that the information is given by forming the information area in a specific pattern shape using the same material as a material forming the non-information area under different forming conditions. In other words, the pattern shape is formed of the same conductive material as the conductive material of the non-information area, and is formed under a firing condition different from a firing condition of the non-information area.

When nano ink or complex ink including, for example, Ag or Cu used for the functional layer such as an electromagnetic wave shielding layer is fired, the structure of Ag or Cu changes, and the particle diameter of Ag or Cu coarsens. Due to the coarsening of the particle diameter of Ag or Cu, the reflection state of the layer using Ag or Cu changes, and the color of the layer changes. In the present example, by utilizing such a phenomenon that the color changes according to firing conditions, a color difference between the pattern shape 13 and the non-information area 110 is generated, while using the same conductive material for the pattern shape 13 and the non-information area 110. Examples of the firing conditions include a firing temperature and a firing time.

For example, Ag nano ink of DNS-0169I manufactured by Daicel Corporation can be used for the non-information area 110 and the pattern shape 13.

For example, as illustrated in FIG. 25, after forming the functional layer 11 on the electronic component 10A, the electronic component 10A provided with the non-information area 110 is put in a thermostatic chamber or an oven. Then, for example, firing is performed at a firing temperature of 200° C. for a firing time of 30 minutes or more. Thus, the non-information area 110 is fixed on the electronic component 10A. After the firing of the non-information area 110 is completed, the electronic component 10A in which the non-information area 110 is formed is taken out from the thermostatic chamber or the oven.

Subsequently, as illustrated in FIG. 26, the Ag nano ink for the pattern shape 13 is applied to the blank area 11′ (see FIG. 25) of the electronic component 10A in which the non-information area 110 is formed. Then, the electronic component 10A to which the Ag nano ink for the pattern shape 13 is applied is put in a thermostatic chamber or an oven. Subsequently, for example, firing is performed at a firing temperature of 120° C. for a firing time of 10 minutes or more. As a result, the pattern shape 13 is fixed on the electronic component 10A.

Thus, the functional-layer-provided electronic component according to the second example is formed. It is preferable that one of the non-information area 110 and the pattern shape 13 on which firing is performed at a higher firing temperature is fired first. Any other suitable material can be used, provided that it is a conductive material that changes color according to firing conditions.

Effects other than effects described in Embodiment 3 are equivalent to those described in Embodiment 1.

According to the related art, a method for forming functional layer on an object such as an electronic circuit module requires forming a marking layer on the functional layer to give information or scraping the functional layer to give information. Accordingly, the layer on the object has to have a thickness greater than needed.

According to one aspect of the present disclosure, a method for forming a functional layer with information is provided, which contributes to further miniaturization and reduction in height of an electronic component, an electronic module, or a combination of these. In embodiments of the present disclosure, since information is given to the same layer as the functional layer, the thickness of the functional-layer-provided electronic component is prevented from increasing even when information is given to the functional layer. Further, the thickness of the electronic component is prevented from increasing since a portion to be removed does not have to be left, and a decrease in the yield of the functional-layer-provided electronic component due to the machining residue is reduced.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention. Any one of the above-described operations may be performed in various other ways, for example, in an order different from the one described above.

Aspects of the present disclosure are as follows, for example.

Aspect 1

According to Aspect 1, a method for forming a functional layer with information includes giving information to the functional layer while forming the functional layer on a surface of an object. The functional layer includes an information area having the information and a non-information area other than the information area. There is a color difference between the information area and the non-information area.

Aspect 2

According to Aspect 2, in the method for forming the functional layer with information of the Aspect 1, the information is given by forming the information area into a specific shape or by forming the information area into a specific pattern shape using a material different from a material of the non-information area or using a same material as a material of the non-information area under a different forming condition.

Aspect 3

According to Aspect 3, in the method for forming the functional layer with information of the Aspect 1 or Aspect 2, the information includes information regarding the object.

Aspect 4

According to Aspect 4, in the method for forming the functional layer with information of the Aspect 2, the specific shape includes an aggregate of dots.

Aspect 5

According to Aspect 5, in the method for forming the functional layer with information of the Aspect 4, maximum widths of the dots viewed from a thickness direction of the functional layer are 0.5 mm or less.

Aspect 6

According to Aspect 6, in the method for forming the functional layer with information of any one of the Aspect 1 to the Aspect 5, the information includes one or more selected from a group consisting of alphanumeric characters, a matrix code, a barcode, and a two-dimensional code corresponding to the information regarding the object.

Aspect 7

According to Aspect 7, in the method for forming the functional layer with information of the Aspect 2, the information area includes a first area and a second area in which the functional layer is thinner than the first area. In one cell of a plurality of cells included in the specific shape, an area of the second area viewed from an upper surface direction of the functional layer is one fourth or more of an area of the one cell viewed from the upper surface direction of the functional layer.

Aspect 8

According to Aspect 8, in the method for forming the functional layer with information of the Aspect 2, a minimum thickness of the functional layer in the information area is one tenth or less of a minimum thickness of the functional layer in an area where the specific shape is not formed.

Aspect 9

According to Aspect 9, in the method for forming the functional layer with information of the Aspect 1, a thickness of the functional layer in the non-information area is 0.1 μm or more and 30 μm or less.

Aspect 10

According to Aspect 10, in the method for forming the functional layer with information of any one of the Aspect 1 to the Aspect 9, the functional layer is formed using a conductive material.

Aspect 11

According to Aspect 11, in the method for forming the functional layer with information of the Aspect 2, the pattern shape is formed of a same conductive material as a conductive material of the non-information area, and is formed under a firing condition different from a firing condition for the non-information area.

Aspect 12

According to Aspect 12, in the method for forming the functional layer with information of any one of the Aspect 1 to the Aspect 12, the functional layer is formed on the object and the information is given to the functional layer by discharging a liquid composition forming the functional layer.

Aspect 13

According to Aspect 13, in the method for forming the functional layer with information of the Aspect 12, the liquid composition is discharged with a line head system.

Aspect 14

According to Aspect 14, in the method for forming the functional layer with information of the Aspect 12, the liquid composition contains a polymerizable compound. The method further includes irradiating the functional layer formed on the object with an active energy ray.

Aspect 15

According to Aspect 15, the method for forming the functional layer with information of the Aspect 2 further includes: acquiring the information; and determining a shape of the information area based on the information.

Aspect 16

According to Aspect 16, the method for forming the functional layer with information of the Aspect 15 further includes determining a position where the information area is to be formed.

Aspect 17

According to Aspect 17, in the method for forming the functional layer with information of the Aspect 16, the position includes a position where ground (GND) lines in the object are concentrated.

Aspect 18

According to Aspect 18, a method for manufacturing an electronic component is provided, in which the object is the electronic component. The method includes forming a functional layer to which information is provided, by the method according to the Aspect 1.

Aspect 19

According to Aspect 19, a functional-layer-provided electronic component is provided, which includes a surface on which a functional layer is formed. The functional layer includes an information area and a non-information area, and has a uniform thickness. Information is given to the information area by a pattern shape having a color difference different from the non-information area.

Aspect 20

According to Aspect 20, in the functional-layer-provided electronic component of the Aspect 19, the information area and the non-information area are formed of a same conductive material.

1. A method for forming a functional layer, the method comprising:
giving information to the functional layer while forming the functional layer on a surface of an object,
the functional layer including an information area having the information and a non-information area other than the information area,
the information area being different in color from the non-information area.

2. The method of claim 1, wherein
the information is given by one of:
1) forming the information area into a specific shape having a thickness different from a thickness of the non-information area; and
2) forming the information area into a specific pattern shape using a material different from a material of the non-information area or using a same material as a material of the non-information area under a different forming condition.

3. The method of claim 1, wherein the information includes information regarding the object.

4. The method of claim 2, wherein the specific shape includes an aggregate of dots.

5. The method of claim 4, wherein the dots viewed from a thickness direction of the functional layer have a maximum width of 0.5 mm or less.

6. The method of claim 1, wherein the information includes one or more selected from a group consisting of alphanumeric characters, a barcode, and a two-dimensional code corresponding to the information regarding the object.

7. The method of claim 2, wherein
the information area includes a first area and a second area in which the functional layer is thinner than the first area, and
the specific shape includes a plurality of cells, the plurality of cells including one cell in which the second area viewed from an upper surface direction of the functional layer has an area of one fourth or more of an area of the one cell viewed from the upper surface direction of the functional layer.

8. The method of claim 2, wherein the functional layer in the information area has a minimum thickness of one tenth or less of a minimum thickness of the functional layer in an area where the specific shape is not formed.

9. The method of claim 1, wherein the functional layer in the non-information area has a thickness of 0.1 μm or more and 30 μm or less.

10. The method of claim 1, wherein the functional layer is formed using a conductive material.

11. The method of claim 2, wherein the specific pattern shape is formed of a same conductive material as a conductive material of the non-information area, and is formed under a firing condition different from a firing condition for the non-information area.

12. The method of claim 1, wherein the functional layer is formed on the object and the information is given to the functional layer by discharging a liquid composition forming the functional layer.

13. The method of claim 12, wherein the liquid composition is discharged with a line head system.

14. The method of claim 12, wherein
the liquid composition comprises a polymerizable compound, and
the method further comprises irradiating the functional layer formed on the object with an active energy ray.

15. The method of claim 2, further comprising:
acquiring the information; and
determining a shape of the information area based on the information.

16. The method of claim 15, further comprising determining a position where the information area is to be formed.

17. The method of claim 16, wherein the position includes a position where ground lines in the object are concentrated.

18. A method for manufacturing an electronic component, the method comprising forming a functional layer to which information is provided according to the method of claim 1, wherein
the object is the electronic component.

19. An electronic component comprising a functional layer as a surface layer,
the functional layer including an information area and a non-information area, and having a uniform thickness, wherein
information is given to the information area by a pattern shape having a color difference different from the non-information area.

20. The electronic component of claim 19, wherein the information area and the non-information area are formed of a same conductive material.
